(19) United States
(12) Patent Application Publication
(10) Pub. No.: US 2026/0280422 A1
(43) Pub. Date: Sep. 17, 2026

(54) SWITCHING POWER SUPPLY MODULE

(71) Applicant: Murata Manufacturing Co., Ltd., Kyoto-fu (JP)

(72) Inventors: Shigeki KOYA, Nagaokakyo-shi (JP); Tatsuya HOSOTANI, Nagaokakyo-shi (JP)

(73) Assignee: Murata Manufacturing Co., Ltd., Kyoto-fu (JP)

(21) Appl. No.: 19/669,616

(22) Filed: May 6, 2026

Related U.S. Application Data
(63) Continuation of application No. PCT/JP2024/029238, filed on Aug. 19, 2024.

(30) Foreign Application Priority Data
Nov. 7, 2023 (JP) 2023-190062

(51) Int. Cl. H02M 3/00; H02M 1/088; H02M 3/158; H05K 7/14

(52) U.S. Cl. CPC H02M 3/003; H02M 1/088; H02M 3/158; H05K 7/1432

(57) ABSTRACT

A switching power supply module includes a circuit board and a plurality of power conversion circuits formed on the circuit board. Each of the multiple power conversion circuits includes an inductor element, a power semiconductor package element, and a smoothing capacitor element. The inductor element includes a metal conductor mainly made of metal and a magnetic core, the metal conductor penetrates the magnetic core, and the metal conductor and the magnetic core are in close contact with each other at a portion where the metal conductor penetrates the magnetic core. The multiple inductor elements constituting the multiple power conversion circuits are mounted on a circuit board. The multiple power semiconductor package elements constituting the multiple power conversion circuits are mounted on a circuit board. A width of the inductor element is smaller than a width of the power semiconductor package element.

### CROSS-REFERENCE TO RELATED APPLICATIONS

This application claims benefit of priority to International Patent Application No. PCT/JP2024/029238, filed Aug. 19, 2024, and to Japanese Patent Application No. 2023-190062, filed Nov. 7, 2023, the entire contents of each are incorporated herein by reference.

### BACKGROUND

### Technical Field

The present disclosure relates to a switching power supply module including a plurality of power conversion circuits.

### Background Art

As disclosed in Japanese Unexamined Patent Application Publication No. 2018-117077, a switching power supply device in the related art has a structure in which a semiconductor IC including a switching element, an inductor, and a capacitor, which constitute a power conversion circuit, are mounted on one surface of a printed circuit board.

In order to drive an advanced processor, which is an advanced semiconductor IC that performs high-speed computation and is used in AI and data centers, it is necessary to supply a large amount of electric power. As semiconductor processes are miniaturized, the operating voltage of the advanced processor decreases, and low-voltage, high-current power needs to be supplied to the advanced processor.

In order to achieve such an increase in current, there has been a demand for a multiphase switching power supply device in which a plurality of power conversion circuits are connected in parallel.

### SUMMARY

In the structure in the related art, the above-described multiphase switching power supply device requires a plurality of power conversion circuits corresponding to the number of phases, and thus the numbers of semiconductor ICs, inductors, and capacitors constituting the respective power conversion circuits increase with the number of phases.

Accordingly, the planar size of the switching power supply device increases. As a result, it becomes difficult to place the switching power supply device in close proximity to a load, a power loss due to a wiring resistance increases, and a power loss increases. Since a power loss is proportional to the square of current, a power loss becomes a more significant problem in the above-described switching power supply device that outputs a large current.

A plurality of semiconductor ICs, each of which is a heat-generating component, are disposed over a large area, and a cooling unit such as a heat sink increases in size. Accordingly, heat dissipation efficiency per predetermined spatial volume decreases.

Accordingly, the present disclosure provides a switching power supply module with which a power loss is suppressed and high heat dissipation efficiency per predetermined spatial volume is achieved.

A switching power supply module according to the present disclosure includes a circuit board and a plurality of power conversion circuits formed on the circuit board. Each of the multiple power conversion circuits includes an inductor element, a power semiconductor package element, and a smoothing capacitor element. The inductor element includes a metal conductor mainly made of metal and a magnetic core, the metal conductor penetrates the magnetic core, and the metal conductor and the magnetic core are in close contact with each other at a portion where the metal conductor penetrates the magnetic core. The circuit board includes a first circuit board and a second circuit board.

The multiple inductor elements constituting the multiple power conversion circuits are mounted on the first circuit board. The multiple power semiconductor package elements constituting the multiple power conversion circuits are mounted on the second circuit board.

A width of the inductor element is smaller than a width of the power semiconductor package element. The multiple inductor elements are arranged parallel to a mounting surface of the first circuit board on which the multiple inductor elements are mounted, and are arranged along a width direction of the multiple inductor elements.

The first circuit board and the second circuit board are arranged such that the mounting surface of the first circuit board on which the multiple inductor elements are mounted and mounting surfaces of the second circuit board on which the multiple power semiconductor package elements are mounted are parallel to each other, the first circuit board and the second circuit board are separated from each other in a direction orthogonal to the mounting surfaces, and the first circuit board and the second circuit board overlap each other in plan view as viewed in the direction orthogonal to the mounting surfaces. The first circuit board and the second circuit board are electrically connected by a connection conductor that connects the first circuit board and the second circuit board in the direction orthogonal to the mounting surfaces.

In this configuration, the power semiconductor package element and the inductor element constituting one power conversion circuit are arranged at different positions in a height direction of the switching power supply module and overlap in plan view. As a result, the planar area of a region where the power conversion circuit is formed is reduced, and the power conversion circuit can be more easily placed in proximity to a load. Since the power semiconductor package element and the inductor element are arranged in a concentrated manner in plan view, the heat generating area in plan view can be reduced and the decrease in heat dissipation efficiency per predetermined spatial volume is suppressed.

According to the present disclosure, a switching power supply module can be provided with which a power loss can be suppressed, a cooling structure per predetermined spatial volume can be simplified, and heat dissipation efficiency can be increased.

### BRIEF DESCRIPTION OF THE DRAWINGS

FIG. 1 is a circuit diagram of a switching power supply module according to a first embodiment;

FIGS. 2A and 2B are external perspective views of the switching power supply module according to the first embodiment;

FIG. 3 is an exploded perspective view of the switching power supply module according to the first embodiment;

FIG. 4 is a top view and a side view of the switching power supply module according to the first embodiment;

FIG. 5 is a top view, a side view, and a bottom view of a first circuit board in the switching power supply module according to the first embodiment;

FIG. 6 is a top view, a side view, and a bottom view of a second circuit board in the switching power supply module according to the first embodiment;

FIG. 7 is a perspective view, a top view, and a side view of an inductor element in the switching power supply module according to the first embodiment;

FIG. 8 is a circuit diagram of a switching power supply module according to a second embodiment;

FIG. 9 is an exploded perspective view of the switching power supply module according to the second embodiment;

FIG. 10 is a top view and a side view of the switching power supply module according to the second embodiment;

FIG. 11 is a circuit diagram of a switching power supply module according to a third embodiment;

FIG. 12 is an exploded perspective view of the switching power supply module according to the third embodiment;

FIG. 13 is a top view and a side view of the switching power supply module according to the third embodiment;

FIG. 14 is an exploded perspective view of a switching power supply module according to a fourth embodiment;

FIG. 15 is an exploded perspective view of a switching power supply module according to a fifth embodiment;

FIG. 16 is a side view of the switching power supply module according to the fifth embodiment;

FIG. 17 is an exploded perspective view of a switching power supply module according to a sixth embodiment;

FIG. 18 is a side view of the switching power supply module according to the sixth embodiment; and

FIG. 19 is an exploded perspective view of a switching power supply module according to a seventh embodiment.

### DETAILED DESCRIPTION

### First Embodiment

A switching power supply module according to a first embodiment of the present disclosure will be described with reference to drawings.

### (Circuit Structure of Switching Power Supply Module 10)

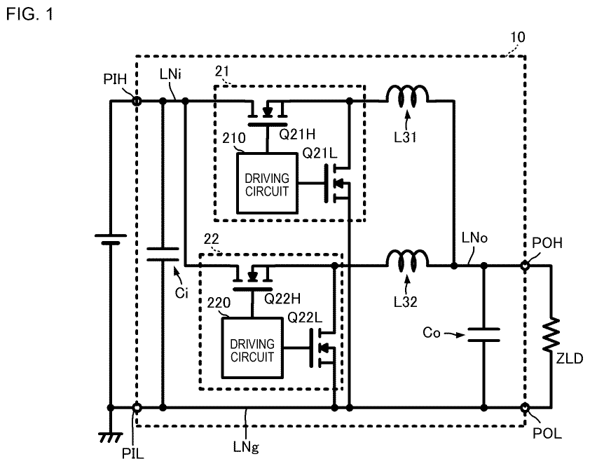

FIG. 1 is a circuit diagram of a switching power supply module according to the first embodiment. As illustrated in FIG. 1, a switching power supply module 10 includes a plurality of power semiconductor package elements (power semiconductor package elements 21 and 22), a plurality of inductors (inductors L31 and L32), an input capacitor Ci, and an output capacitor Co. The output capacitor Co corresponds to a “smoothing capacitor” according to the present disclosure.

The switching power supply module 10 includes a pair of input terminals PIH and PIL, a pair of output terminals POH and POL, an input-side wiring line LNi, an output-side wiring line LNo, and a reference potential wiring line LNg.

A DC power supply is connected to the input terminals PIH and PIL. The input terminal PIH is connected to a positive terminal of the DC power supply, and the input terminal PIL is connected to a negative terminal of the DC power supply.

The input capacitor Ci is connected between the input terminals PIH and PIL. The input-side wiring line LNi is connected to the input terminal PIH, and the reference potential wiring line LNg is connected to the input terminal PIL.

The input terminals PIH and PIL are connected to each of the power semiconductor package elements 21 and 22.

The power semiconductor package element 21 includes a driving circuit 210, a power semiconductor element Q21H, and a power semiconductor element Q21L. The driving circuit 210 is configured as an analog circuit. The power semiconductor elements Q21H and Q21L are formed of, for example, power FETs. The driving circuit 210 and the power semiconductor elements Q21H and Q21L are integrally formed in a single analog IC.

A drain terminal of the power semiconductor element Q21H is connected to the input-side wiring line LNi. A source terminal of the power semiconductor element Q21H is connected to a drain terminal of the power semiconductor element Q21L. A source terminal of the power semiconductor element Q21L is connected to the reference potential wiring line LNg.

A gate terminal of the power semiconductor element Q21H and a gate terminal of the power semiconductor element Q21L are connected to the driving circuit 210. Although not illustrated, the driving circuit 210 receives the supply of power from the DC power supply through the input-side wiring line LNi. The driving circuit 210 controls the driving of the power semiconductor elements Q21H and Q21L. As a result, the power semiconductor elements Q21H and Q21L are subjected to switching control at a predetermined switching frequency (switching period).

The power semiconductor package element 22 includes a driving circuit 220, a power semiconductor element Q22H, and a power semiconductor element Q22L. The driving circuit 220 is configured as an analog circuit. The power semiconductor elements Q22H and Q22L are formed of, for example, power FETs. The driving circuit 220 and the power semiconductor elements Q22H and Q22L are integrally formed in a single analog IC.

A drain terminal of the power semiconductor element Q22H is connected to the input-side wiring line LNi. A source terminal of the power semiconductor element Q22H is connected to a drain terminal of the power semiconductor element Q22L. A source terminal of the power semiconductor element Q22L is connected to the reference potential wiring line LNg.

A gate terminal of the power semiconductor element Q22H and a gate terminal of the power semiconductor element Q22L are connected to the driving circuit 220. Although not illustrated, the driving circuit 220 receives the supply of power from the DC power supply through the input-side wiring line LNi. The driving circuit 220 controls the driving of the power semiconductor elements Q22H and Q22L. As a result, the power semiconductor elements Q22H and Q22L are subjected to switching control at a predetermined switching frequency (switching period).

One terminal of the inductor L31 is connected to an output terminal of the power semiconductor package element 21 (a node of the source terminal of the power semiconductor element Q21H and the gate terminal of the power semiconductor element Q21L).

One terminal of the inductor L32 is connected to an output terminal of the power semiconductor package element 22 (a node of the source terminal of the power semiconductor element Q22H and the gate terminal of the power semiconductor element Q22L).

The other terminal of the inductor L31 and the other terminal of the inductor L32 are connected to the output-side wiring line LNo.

The output-side wiring line LNo is connected to the output terminal POH. The output terminal POL is connected to the reference potential wiring line LNg.

The output capacitor Co is connected between the output terminals POH and POL.

A load ZLD is connected between the output terminals POH and POL.

With such a structure, the switching power supply module 10 includes a first power conversion circuit including the power semiconductor package element 21, the inductor L31, and the output capacitor Co, and a second power conversion circuit including the power semiconductor package element 22, the inductor L32, and the output capacitor Co.

The driving circuit 210 in the power semiconductor package element 21 and the driving circuit 220 in the power semiconductor package element 22 are connected to an MPU (not illustrated).

The MPU performs multiphase control upon the power semiconductor package elements 21 and 22. In this case, the MPU performs two-phase multiphase control. As a result, in the switching power supply module 10, the first power conversion circuit and the second power conversion circuit operate in a multiphase manner to supply power to the load ZLD.

### (Structure of Switching Power Supply Module 10)

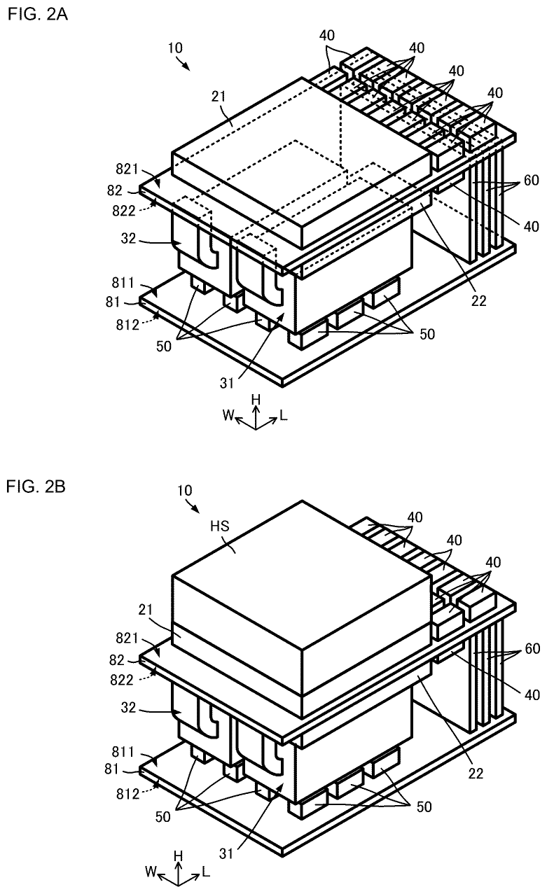

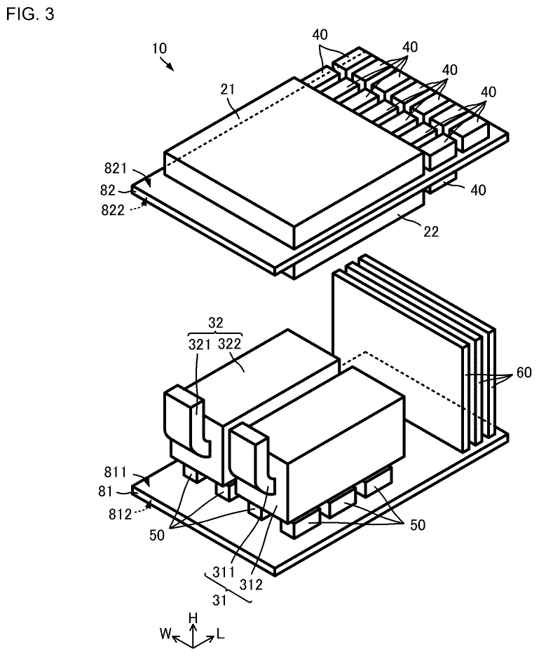

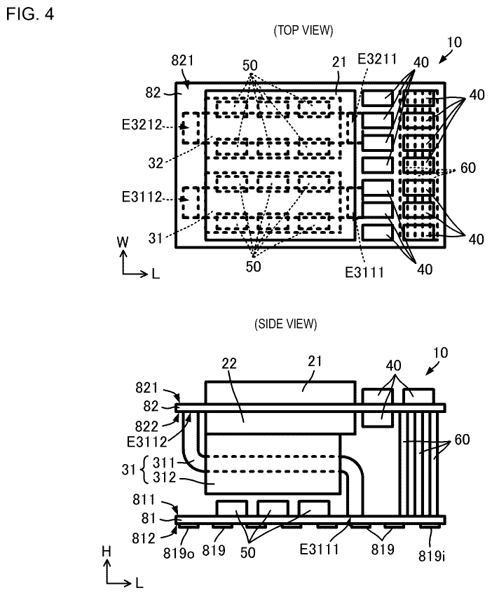

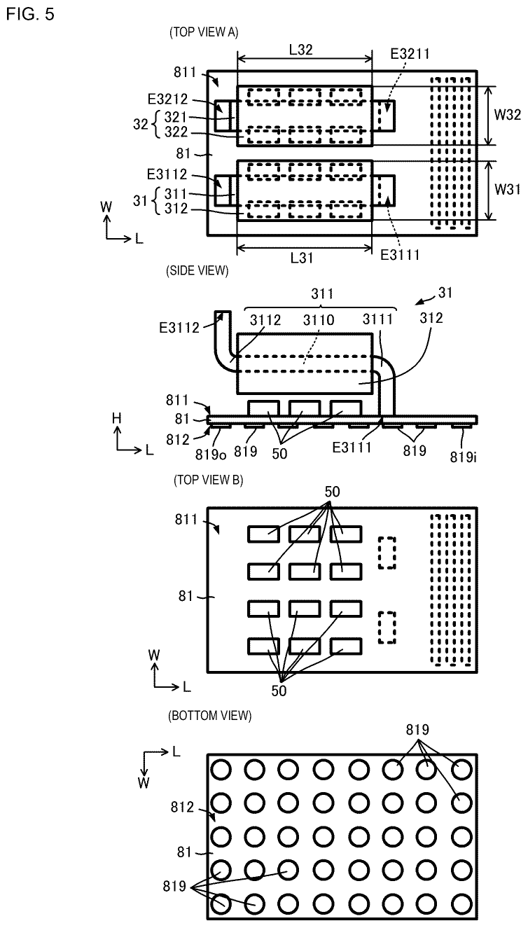

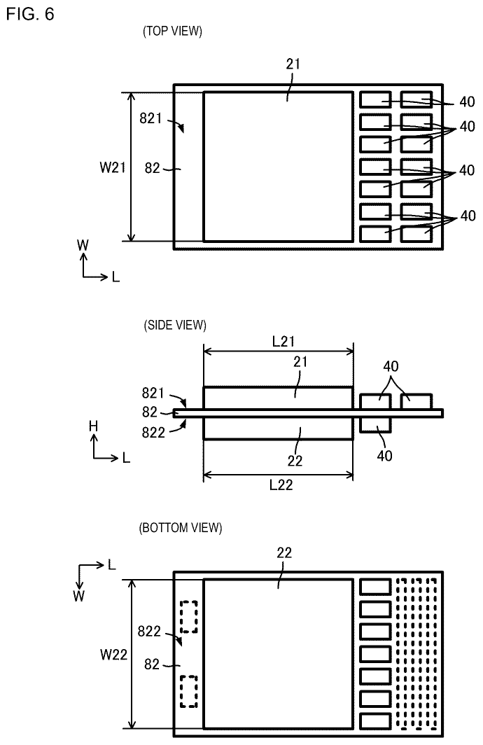

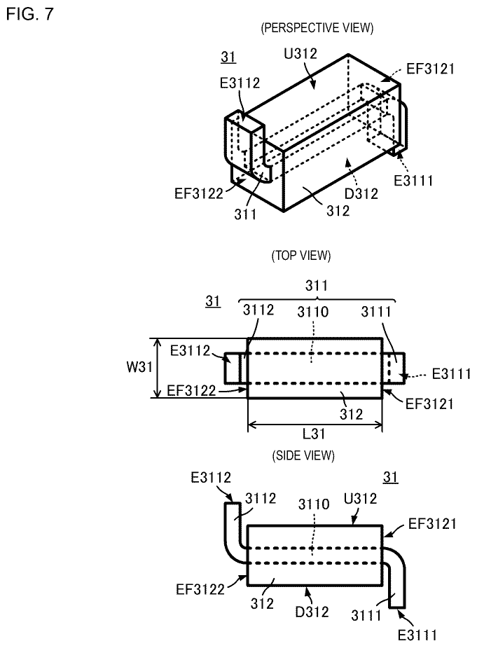

FIGS. 2A and 2B are external perspective views of the switching power supply module according to the first embodiment. FIG. 2A illustrates a state in which a heat sink is omitted, and FIG. 2B illustrates a state in which the heat sink is mounted. FIG. 3 is an exploded perspective view of the switching power supply module according to the first embodiment. FIG. 4 is a top view and a side view of the switching power supply module according to the first embodiment. FIG. 5 is a top view, a side view, and a bottom view of a first circuit board in the switching power supply module according to the first embodiment. FIG. 6 is a top view, a side view, and a bottom view of a second circuit board in the switching power supply module according to the first embodiment. FIG. 7 is a perspective view, a top view, and a side view of an inductor element in the switching power supply module according to the first embodiment. In the drawings of respective embodiments including the present embodiment, lead lines and reference numerals are appropriately omitted for clarity to the extent that they can be readily understood from the description of other portions.

The switching power supply module 10 includes the multiple power semiconductor package elements 21 and 22, a plurality of inductor elements 31 and 32, a plurality of capacitor elements 40, a plurality of capacitor elements 50, a plurality of connection conductors 60, circuit boards 81 and 82, and a heat sink HS.

The power semiconductor package elements 21 and 22 are formed as surface-mounted analog ICs and correspond to the power semiconductor package elements 21 and 22, respectively, in the circuit diagram of FIG. 1.

The inductor elements 31 and 32 are formed as surface-mounted elements. The inductor element 31 corresponds to the inductor L31 in the circuit diagram of FIG. 1, and the inductor element 32 corresponds to the inductor L32 in the circuit diagram of FIG. 1. FIG. 7 illustrates the inductor element 31, and the inductor elements 31 and 32 have the same structure.

As illustrated in FIG. 7, the inductor element 31 includes a metal conductor 311 and a magnetic core 312. The metal conductor 311 is a rod-shaped member having bent portions (curved portions) in the middle thereof. The metal conductor 311 includes a main body portion 3110, a first end portion 3111, and a second end portion 3112.

The first end portion 3111 is connected to one end of the main body portion 3110 in an extending direction of the main body portion 3110 (a conduction direction toward the magnetic core 312). The second end portion 3112 is connected to the other end of the main body portion 3110 in the extending direction of the main body portion 3110. The extending directions of the first end portion 3111 and the second end portion 3112 are orthogonal to the extending direction of the main body portion 3110. The extending directions of the first end portion 3111 and the second end portion 3112 are opposite to each other. An end portion of the first end portion 3111 (an end portion opposite to an end portion connected to the main body portion 3110) is a first terminal E3111 of the inductor element 31. An end portion of the second end portion 3112 (an end portion opposite to an end portion connected to the main body portion 3110) is a second terminal E3112 of the inductor element 31.

The magnetic core 312 has a substantially rectangular parallelepiped shape and accommodates the main body portion 3110 of the metal conductor 311 therein. The magnetic core 312 is in close contact with a side surface of the main body portion 3110 (a surface parallel to a penetration direction at a penetration portion where the main body portion 3110 penetrates the magnetic core 312).

The first end portion 3111 protrudes from a first end face EF3121 of the magnetic core 312 to the outside of the magnetic core 312 and extends toward a rear surface D312 side of the magnetic core 312. The end of the first end portion 3111 (the first terminal E3111) protrudes beyond the rear surface D312 of the magnetic core 312.

The second end portion 3112 protrudes from a second end face EF3122 of the magnetic core 312 to the outside of the magnetic core 312 and extends toward a front surface U312 side of the magnetic core 312. The end of the second end portion 3112 (the second terminal E3112) protrudes beyond the front surface U312 of the magnetic core 312.

The shapes of the inductor elements 31 and 32 are not limited thereto, and any shape may be employed as long as the first terminal E3111 protrudes toward the rear surface D312 side of the magnetic core 312 and the second terminal E3112 protrudes toward the front surface U312 side of the magnetic core 312.

The multiple capacitor elements 40 are formed as surface-mounted elements. The multiple capacitor elements 40 correspond to the input capacitor Ci illustrated in FIG. 1. The multiple capacitor elements 40 are, for example, chip-type capacitor elements each having terminal electrodes at both ends.

The multiple capacitor elements 50 are formed as surface-mounted elements. The multiple capacitor elements 50 correspond to the output capacitor Co illustrated in FIG. 1. The multiple capacitor elements 50 are, for example, chip-type capacitor elements each having terminal electrodes at both ends.

### (Mounting Structure of Circuit Board 81)

The circuit board 81 has a substantially rectangular shape in plan view and has a front surface 811 and a rear surface 812. The circuit board 81 is mainly formed of an insulating resin, and conductor patterns for implementing the switching power supply module 10 are formed thereon. In the present embodiment, the circuit board 81 corresponds to the first circuit board, the front surface 811 corresponds to a first front surface, and the rear surface 812 corresponds to a first rear surface.

For example, as illustrated in FIG. 5, the inductor elements 31 and 32, the multiple capacitor elements 50, and the multiple connection conductors 60 are mounted on the front surface 811 of the circuit board 81. That is, the front surface 811 is a mounting surface for the inductor elements 31 and 32, the multiple capacitor elements 50, and the multiple connection conductors 60. More specifically, the mounting pattern is as follows.

The inductor elements 31 and 32 are mounted such that their respective longitudinal directions (extending directions of the main body portion 3110 of the metal conductor 311 and a main body portion of a metal conductor 321) are parallel to a first direction (an L direction in each drawing) on the circuit board 81. The inductor elements 31 and 32 are mounted adjacent to each other in a second direction (a W direction in each drawing) on the circuit board 81.

The inductor elements 31 and 32 are mounted such that the extending directions of the main body portions thereof are substantially parallel to the front surface 811 of the circuit board 81. The inductor elements 31 and 32 are mounted such that the extending directions of the main body portions thereof are parallel to the first direction (the L direction) of the circuit board 81.

The inductor element 31 is mounted such that the magnetic core 312 is positioned apart from the front surface 811. The inductor element 32 is mounted such that a magnetic core 322 is positioned apart from the front surface 811. A distance between the magnetic core 312 and the front surface 811 and a distance between the magnetic core 322 and the front surface 811 are substantially the same.

The first terminal E3111 of the metal conductor 311 of the inductor element 31 and a first terminal E3211 of the metal conductor 321 of the inductor element 32 are joined to land conductors on the front surface 811 of the circuit board 81 by a conductive joining material, such as solder.

The second terminal E3112 of the inductor element 31 and a second terminal E3212 of the inductor element 32 are located near one end of the circuit board 81 in the first direction.

The multiple capacitor elements 50 are mounted, in a height direction (an H direction in each drawing), between the front surface 811 and the magnetic core 312 of the inductor element 31 or the magnetic core 322 of the inductor element 32. The multiple capacitor elements 50 are mounted in a region that substantially overlaps the inductor element 31 or 32 in plan view of the front surface 811. The multiple capacitor elements 50 are arranged in a two-dimensional array along two orthogonal axes in the first direction and the second direction.

Each of the multiple connection conductors 60 is formed of a metal flat plate having a flat surface, or an insulating substrate having a flat surface on which a conductor pattern is formed (e.g., a glass-epoxy substrate). A length of the multiple connection conductors 60 in the second direction (the W direction) is substantially the same as the length of each of the circuit boards 81 and 82 in the second direction (the W direction).

The multiple connection conductors 60 are mounted near the other end of the circuit board 81 in the first direction (the L direction in each drawing) on the front surface 811. The multiple connection conductors 60 are arranged such that the flat surfaces thereof are parallel to a direction orthogonal to the front surface 811 and parallel to the second direction (the W direction in each drawing). The multiple connection conductors 60 are spaced apart from each other in the first direction.

Multiple external connection conductors 819 are formed on the rear surface 812 of the circuit board 81. The multiple external connection conductors 819 are, for example, circular in plan view and are arranged in a two-dimensional array along the two orthogonal axes in the first direction and the second direction. Apart of the multiple external connection conductors 819 constitutes the input terminals PIH and PIL and the output terminals POH and POL in the circuit of FIG. 1.

### (Mounting Structure of Circuit Board 82)

The circuit board 82 has a substantially rectangular shape in plan view and has a front surface 821 and a rear surface 822. The circuit board 82 is mainly formed of an insulating resin, and conductor patterns for implementing the switching power supply module 10 are formed thereon. The circuit board 82 has a planar shape substantially the same as that of the circuit board 81. In the present embodiment, the circuit board 82 corresponds to the second circuit board, the front surface 821 corresponds to a second front surface, and the rear surface 822 corresponds to a second rear surface.

For example, as illustrated in FIG. 6, the power semiconductor package element 21 and the multiple capacitor elements 40 are mounted on the front surface 821 of the circuit board 82. That is, the front surface 821 is a mounting surface for the power semiconductor package element 21 and the multiple capacitor elements 40.

The power semiconductor package element 21 and a group of the multiple capacitor elements 40 are arranged in the first direction (the L direction in each drawing) on the front surface 821. The power semiconductor package element 21 is disposed closer to one end side of the front surface 821 than the group of the multiple capacitor elements 40.

On the front surface 821, the multiple capacitor elements 40 are arranged in a two-dimensional array along two orthogonal axes in the first direction and the second direction.

The power semiconductor package element 22 and the multiple capacitor elements 40 are mounted on the rear surface 822 of the circuit board 82. That is, the rear surface 822 is a mounting surface for the power semiconductor package element 22 and the multiple capacitor elements 40.

The power semiconductor package element 22 and a group of the multiple capacitor elements 40 are arranged in the first direction (the L direction in each drawing) on the rear surface 822. The power semiconductor package element 22 is disposed closer to one end side of the rear surface 822 than the group of the multiple capacitor elements 40.

The power semiconductor package element 22 overlaps the power semiconductor package element 21 in plan view of the circuit board 82.

At one end of the rear surface 822 in the first direction, land conductors on which the second terminal E3112 of the inductor element 31 and the second terminal E3212 of the inductor element 32 are mounted are formed (see dotted lines illustrated in FIG. 6). At the other end of the rear surface 822 in the first direction, the multiple capacitor elements 40 are not mounted, and land conductors on which the multiple connection conductors 60 are mounted are formed (see dotted lines illustrated in FIG. 6). That is, the rear surface 822 is also a mounting surface for the multiple connection conductors 60, the second terminal E3112 of the inductor element 31, and the second terminal E3212 of the inductor element 32.

### (Stacked Structure of Circuit Boards 81 and 82)

The circuit board 82 is disposed on the front surface 811 side of the circuit board 81. The rear surface 822 of the circuit board 82 faces the front surface 811 of the circuit board 81. That is, the circuit boards 82 and 81 overlap each other as viewed in a height direction (the H direction in each drawing) (in plan view). The longitudinal direction of the circuit board 81 is parallel to the longitudinal direction of the circuit board 82.

The circuit boards 81 and 82 are separated from each other in the height direction (the H direction in each drawing).

The second terminal E3112 of the inductor element 31, the second terminal E3212 of the inductor element 32, and the multiple connection conductors 60 are mounted on the rear surface 822 of the circuit board 82. As a result, the circuit boards 81 and 82 are electrically connected and physically connected. The multiple connection conductors 60 constitute the input-side wiring line LNi and the reference potential wiring line LNg in the circuit illustrated in FIG. 1.

In such a structure, in plan view of the switching power supply module 10, the inductor elements 31 and 32 overlap the power semiconductor package elements 21 and 22.

More specifically, a width W31 of the inductor element 31 and a width W32 of the inductor element 32 (see, for example, FIG. 5) are smaller than and are substantially one-half of a width W21 of the power semiconductor package element 21 and a width W22 of the power semiconductor package element 22 (see, for example, FIG. 6). As a result, in the width direction of the switching power supply module 10, the inductor elements 31 and 32 substantially overlap the entire power semiconductor package elements 21 and 22.

A length L31 of the inductor element 31 and a length L32 of the inductor element 32 (see, for example, FIG. 5) are smaller than a length L21 of the power semiconductor package element 21 and a length L22 of the power semiconductor package element 22. As a result, in the length direction of the switching power supply module 10, the inductor elements 31 and 32 substantially overlap the entire power semiconductor package elements 21 and 22.

Thus, in the present embodiment, both in the length direction and the width direction, the inductor elements 31 and 32 substantially overlap the entire power semiconductor package elements 21 and 22.

### Example of Operational Effects Achieved by the Above Structure

With such a structure, the power semiconductor package element and the inductor element constituting one power conversion circuit are not arranged side by side in a plane, but are arranged in a height direction. As a result, a planar area of one power conversion circuit can be reduced.

A planar area of the switching power supply module 10 is reduced, and the power semiconductor package elements 21 and 22 and the inductor elements 31 and 32 can be more easily disposed in close proximity to the load ZLD. As a result, the loss in supplying power to the load ZLD can be suppressed in the switching power supply module 10.

The power semiconductor package elements 21 and 22 and the inductor elements 31 and 32 are arranged in a concentrated manner in plan view. As a result, a heat-generating area can be reduced in plan view in the switching power supply module 10. In the switching power supply module 10, heat generated by electronic components disposed at various locations can be confined within a predetermined spatial volume and a temperature distribution within the predetermined spatial volume can be made uniform. Accordingly, in the switching power supply module 10, a cooling structure can be simplified, the decrease in heat dissipation efficiency per predetermined spatial volume can be suppressed, and heat dissipation efficiency can be increased.

At this time, as illustrated in FIG. 2B, the heat sink HS is disposed at a position overlapping the power semiconductor package elements 21 and 22 and the inductor elements 31 and 32 to come into contact with the uppermost power semiconductor package element 21 in the switching power supply module 10. As a result, the switching power supply module 10 can efficiently dissipate heat.

Since the planar area of the heat sink HS can be made substantially the same as that of the power semiconductor package element 21, the increase in the planar area of the switching power supply module 10 with the heat sink HS mounted thereon can be suppressed and the switching power supply module 10 can be reduced in size.

The inductor elements 31 and 32 are connected to the circuit boards 81 and 82. That is, the inductor elements 31 and 32 also have a function of electrically connecting the circuit boards 81 and 82. As a result, even when the circuit boards 81 and 82 are separated from each other in the height direction, it is unnecessary to additionally provide a conductor pattern for connecting the power semiconductor package element 21 and the inductor element 31 and a conductor pattern for connecting the power semiconductor package element 22 and the inductor element 32. As a result, the number of constituent elements of the switching power supply module 10 can be reduced, and the switching power supply module 10 can be reduced in size.

In this structure, the power semiconductor package element 21 and the inductor element 31 overlap in plan view, and the second terminal E3112 of the inductor element 31 is connected to the circuit board 82 near the power semiconductor package element 21 in plan view.

As a result, a connection distance between the power semiconductor package element 21 and the inductor element 31 can be shortened in the switching power supply module 10. Similarly, the power semiconductor package element 22 and the inductor element 32 overlap in plan view, and the second terminal E3212 of the inductor element 32 is connected to the circuit board 82 near the power semiconductor package element 22 in plan view. As a result, a connection distance between the power semiconductor package element 22 and the inductor element 32 can be shortened in the switching power supply module 10.

The metal conductor 311 of the inductor element 31 has a cross-sectional area larger than that of the conductor pattern of the circuit board 82. Accordingly, an electrical resistance between the power semiconductor package element 21 and the inductor element 31 can be reduced. Similarly, the metal conductor 321 of the inductor element 32 has a cross-sectional area larger than that of the conductor pattern of the circuit board 82. Accordingly, an electrical resistance between the power semiconductor package element 22 and the inductor element 32 can be reduced.

In the inductor element 31, the main body portion 3110 of the metal conductor 311 is in close contact with the magnetic core 312. In the inductor element 32, the main body portion of the metal conductor 321 is in close contact with the magnetic core 322. As a result, in the inductor elements 31 and 32, the close contact between the metal conductor and the magnetic core enables a higher magnetic flux density relative to a generated magnetic flux.

Accordingly, the outer sizes of the inductor elements 31 and 32 can be reduced to achieve a desired inductance. As a result, the inductor elements 31 and 32 can be more easily arranged to overlap the power semiconductor package elements 21 and 22. Accordingly, in the switching power supply module 10, heat-generating portions can be more easily concentrated in plan view and heat dissipation efficiency can be improved with more certainty.

Since the input-side wiring line LNi and the reference potential wiring line LNg are formed by the connection conductors 60 and the connection conductors 60 are flat plates, the electrical resistance of the input-side wiring line LNi and the reference potential wiring line LNg can be reduced in the switching power supply module 10.

By overlapping the external connection conductors 819i (see the side view illustrated in FIG. 4) constituting the input terminals PIH and PIL with the multiple connection conductors 60 in plan view, or by disposing the external connection conductors 819i in close proximity to the multiple connection conductors 60 in plan view, wiring lines between the input terminals PIH and PIL, and the multiple capacitor elements 40 and the power semiconductor package elements 21 and 22, can be shortened.

By disposing external connection conductors 819o (see the side view illustrated in FIG. 4) constituting the output terminals POH and POL in close proximity to the multiple capacitor elements 50 in plan view, or by overlapping the external connection conductors 819o with the multiple capacitor elements 50 in plan view, wiring lines between the multiple capacitor elements 50 and the inductor elements 31 and 32, and the output terminals POH and POL, can be shortened.

In the above-described structure, current flows, in a substantially counterclockwise direction, in the order of the input terminals PIH and PIL, the multiple capacitor elements 40 (the input capacitor Ci), the multiple power semiconductor package elements 21 and 22, the multiple inductor elements 31 and 32, the multiple capacitor elements 50 (the output capacitor Co), and the output terminals POH and POL, as can be understood with reference to, for example, the side view illustrated in FIG. 4. As a result, wiring lines can be shortened in the switching power supply module 10.

### Second Embodiment

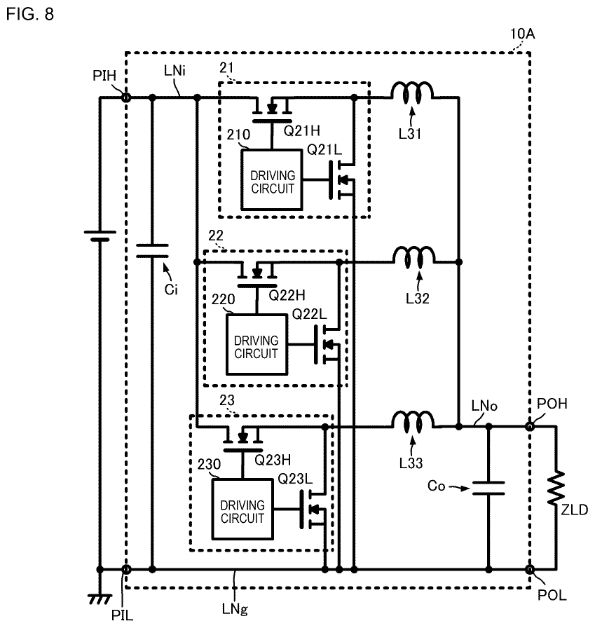

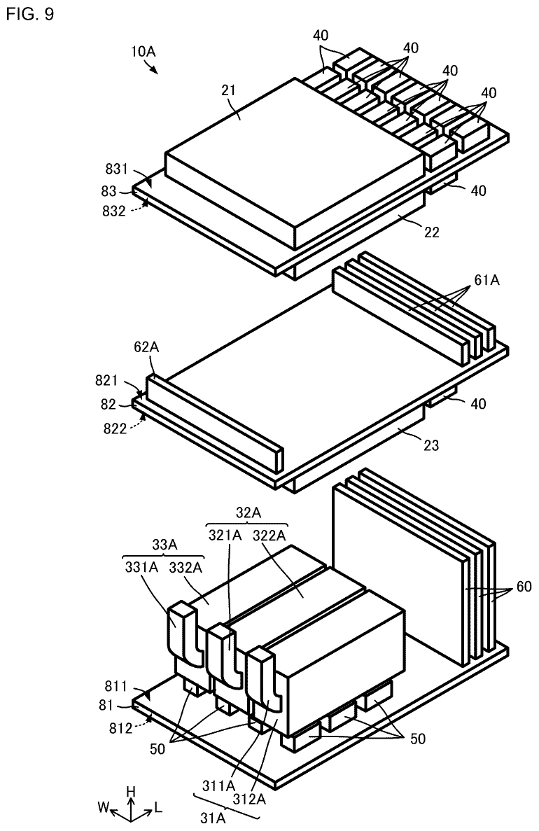

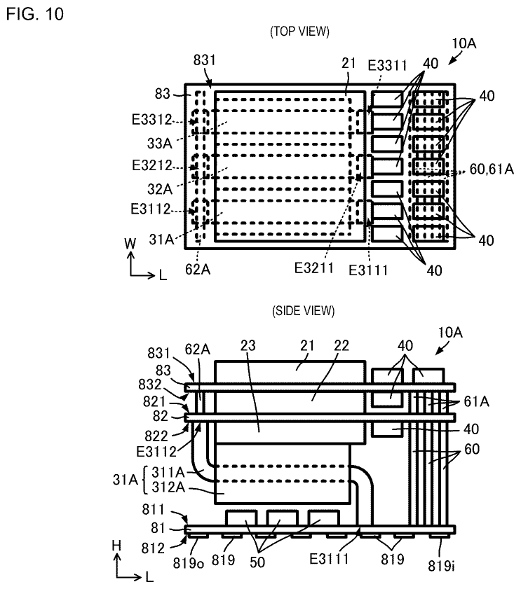

A switching power supply module according to a second embodiment of the present disclosure will be described with reference to drawings. FIG. 8 is a circuit diagram of a switching power supply module according to the second embodiment. FIG. 9 is an exploded perspective view of the switching power supply module according to the second embodiment. FIG. 10 is a top view and a side view of the switching power supply module according to the second embodiment.

The switching power supply module 10A according to the second embodiment differs from the switching power supply module 10 according to the first embodiment in that it has a structure corresponding to three-phase multiphase control. For the switching power supply module 10A, description of portions similar to those of the switching power supply module 10 will be omitted as appropriate.

### (Circuit Structure of Switching Power Supply Module 10A)

As illustrated in FIG. 8, the switching power supply module 10A includes a plurality of power semiconductor package elements (the power semiconductor package elements 21 and 22 and a power semiconductor package element 23), a plurality of inductors (the inductors L31 and L32 and an inductor L33), the input capacitor Ci, and the output capacitor Co.

The power semiconductor package element 23 includes a driving circuit 230, a power semiconductor element Q23H, and a power semiconductor element Q23L. The power semiconductor package element 23 has substantially the same structure as the power semiconductor package elements 21 and 22.

The power semiconductor package element 23 is connected in parallel to the power semiconductor package elements 21 and 22.

One terminal of the inductor L33 is connected to an output terminal of the power semiconductor package element 23. The other terminal of the inductor L33 is connected to the output-side wiring line LNo.

With such a structure, the switching power supply module 10A achieves three-phase multiphase control.

### (Structure of Switching Power Supply Module 10A)

As illustrated in FIGS. 9 and 10, the switching power supply module 10A differs from the switching power supply module 10 according to the first embodiment in that, in outline, three circuit boards are used. For the switching power supply module 10A, description of portions similar to those of the switching power supply module 10 will be omitted as appropriate.

The switching power supply module 10A includes the multiple power semiconductor package elements 21, 22, and 23, multiple inductor elements 31A, 32A, and 33A, the multiple capacitor elements 40, the multiple capacitor elements 50, the multiple connection conductors 60, multiple connection conductors 61A, a connection conductor 62A, the circuit boards 81 and 82, and a circuit board 83.

The power semiconductor package elements 21, 22, and 23 are formed as surface-mounted analog ICs and correspond to the power semiconductor package elements 21, 22, and 23, respectively, in the circuit diagram of FIG. 8.

The inductor elements 31A, 32A, and 33A are formed as surface-mounted elements. The inductor elements 31A, 32A, and 33A correspond to the inductors L31, L32, and L33, respectively, in the circuit diagram of FIG. 8.

The inductor element 31A includes a metal conductor 311A and a magnetic core 312A. The inductor element 32A includes a metal conductor 321A and a magnetic core 322A. The inductor element 33A includes a metal conductor 331A and a magnetic core 332A. The schematic structures of the inductor elements 31A, 32A, and 33A are substantially the same as those of the inductor elements 31 and 32.

The widths of the inductor elements 31A, 32A, and 33A are substantially one-third of the widths of the power semiconductor package elements 21, 22, and 23.

The multiple connection conductors 61A and the connection conductor 62A have substantially the same structure as the connection conductor 60.

The circuit board 83 has a front surface 831 and a rear surface 832, and conductor patterns for implementing the switching power supply module 10A are formed thereon, similarly to the circuit boards 81 and 82.

### (Mounting Structure of Circuit Board 81)

The multiple inductor elements 31A, 32A, and 33A, the multiple capacitor elements 50, and the multiple connection conductors 60 are mounted on the front surface 811 of the circuit board 81.

The inductor elements 31A, 32A, and 33A are mounted adjacent to each other in the second direction (the W direction in each drawing) on the circuit board 81.

The first terminal E3111 of the metal conductor 311A of the inductor element 31A, the first terminal E3211 of the metal conductor 321A of the inductor element 32A, and a first terminal E3311 of the metal conductor 331A of the inductor element 33A are joined to land conductors on the front surface 811 of the circuit board 81 by a conductive joining material, such as solder.

The second terminal E3112 of the inductor element 31A, the second terminal E3212 of the inductor element 32A, and a second terminal E3312 of the inductor element 33A are located near one end of the circuit board 81 in the first direction.

### (Mounting Structure of Circuit Board 82)

The power semiconductor package element 23, the multiple capacitor elements 40, the multiple connection conductors 61A, and the connection conductor 62A are mounted on the circuit board 82.

The multiple connection conductors 61A and the connection conductor 62A are mounted on the front surface 821 of the circuit board 82. The multiple connection conductors 61A are mounted at positions overlapping the multiple connection conductors 60 in plan view. In plan view, the connection conductor 62A is mounted at a position overlapping the second terminals of the multiple inductor elements 31A, 32A, and 33A.

The power semiconductor package element 23 and the multiple capacitor elements 40 are mounted on the rear surface 822 of the circuit board 82.

### (Mounting Structure of Circuit Board 83)

The power semiconductor package elements 21 and 22 and the multiple capacitor elements 40 are mounted on the circuit board 83.

The power semiconductor package element 21 and the multiple capacitor elements 40 are mounted on the front surface 831 of the circuit board 83. The power semiconductor package element 22 and the multiple capacitor elements 40 are mounted on the rear surface 832 of the circuit board 83.

### (Stacked Structure of Multiple Circuit Boards 81, 82, and 83)

The circuit board 82 is disposed on the front surface 811 side of the circuit board 81. The rear surface 822 of the circuit board 82 faces the front surface 811 of the circuit board 81. That is, the circuit boards 82 and 81 overlap each other as viewed in the height direction (the H direction in each drawing) (in plan view). The longitudinal direction of the circuit board 82 is parallel to the longitudinal direction of the circuit board 81. The circuit boards 82 and 81 are separated from each other in the height direction (the H direction in each drawing).

The circuit board 83 is disposed on the front surface 821 side of the circuit board 82. The rear surface 832 of the circuit board 83 faces the front surface 821 of the circuit board 82. That is, the circuit boards 83 and 82 overlap each other as viewed in the height direction (the H direction in each drawing) (in plan view). The longitudinal direction of the circuit board 83 is parallel to the longitudinal direction of the circuit board 82. The circuit boards 83 and 82 are separated from each other in the height direction (the H direction in each drawing).

The second terminal E3112 of the inductor element 31A, the second terminal E3212 of the inductor element 32A, the second terminal E3312 of the inductor element 33A, and the multiple connection conductors 60 are mounted on the rear surface 822 of the circuit board 82. As a result, the circuit boards 81 and 82 are electrically connected and physically connected.

The multiple connection conductors 61A and the connection conductor 62A are mounted on the rear surface 832 of the circuit board 83. As a result, the circuit boards 82 and 83 are electrically connected and physically connected.

In such a structure, in plan view of the switching power supply module 10A, the power semiconductor package elements 21, 22, and 23 overlap one another. In plan view of the switching power supply module 10A, the inductor elements 31A, 32A, and 33A overlap the power semiconductor package elements 21, 22, and 23.

With such a structure, the switching power supply module 10A can have substantially the same planar area as the switching power supply module 10 for performing two-phase multiphase control, while achieving three-phase multiphase control. The switching power supply module 10A can achieve substantially the same advantageous effects as the switching power supply module 10.

In the switching power supply module 10A, the multiple connection conductors 61A overlap the multiple connection conductors 60 in plan view. As a result, in the switching power supply module 10A, connection distances between the input terminal PIH and the output terminal POH, and the multiple power semiconductor package elements 21, 22, and 23, can be shortened and a power loss can be suppressed.

In the switching power supply module 10A, the connection conductor 62A overlaps the second terminals of the multiple inductor elements 31A, 32A, and 33A. As a result, in the switching power supply module 10A, a connection distance between the power semiconductor package element 21 and the inductor element 31A, a connection distance between the power semiconductor package element 22 and the inductor element 32A, and a connection distance between the power semiconductor package element 23 and the inductor element 33A can be shortened and a power loss can be suppressed.

### Third Embodiment

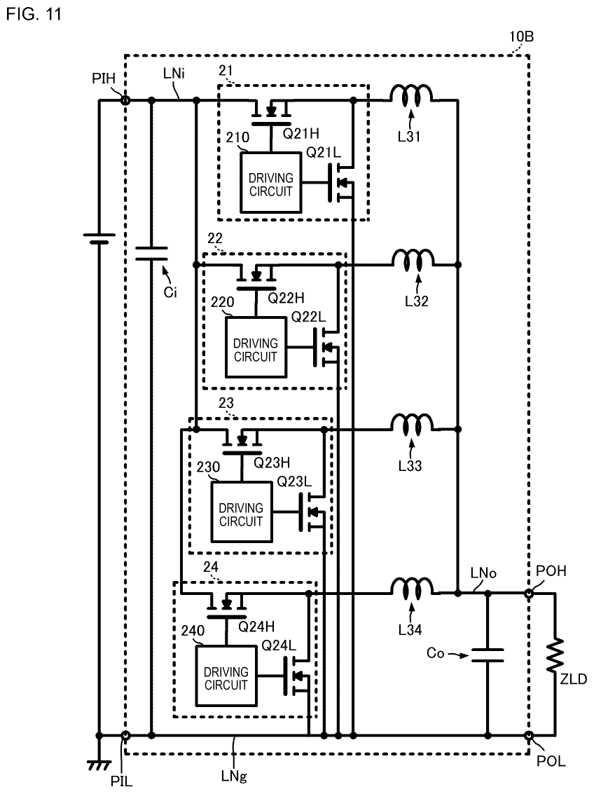

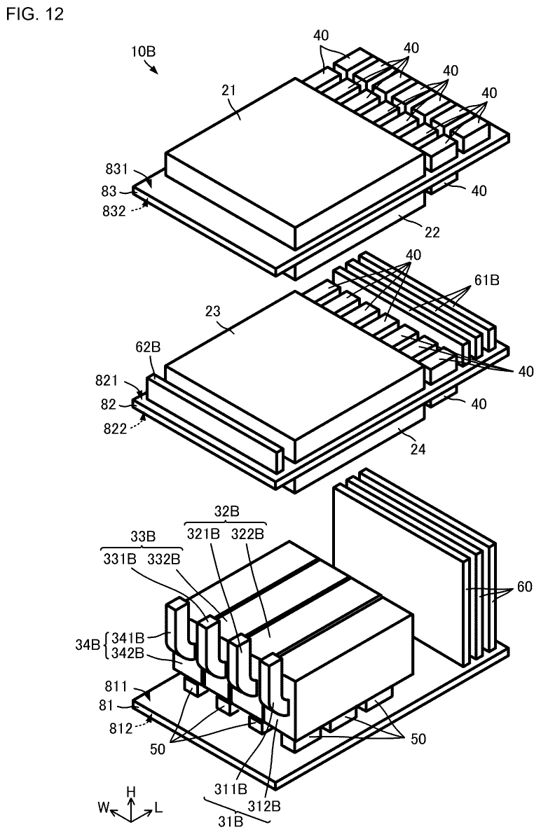

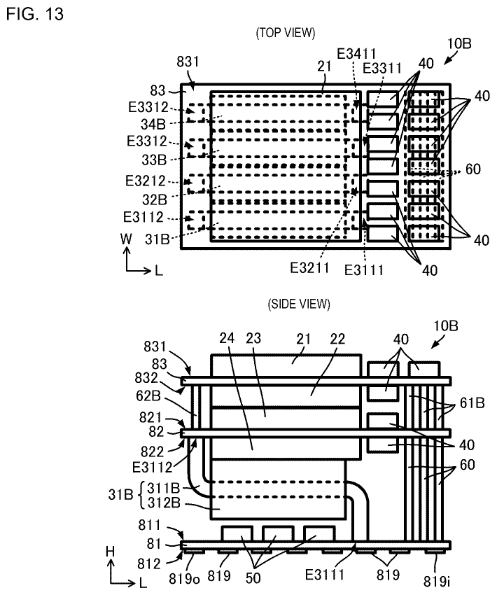

A switching power supply module according to a third embodiment of the present disclosure will be described with reference to drawings. FIG. 11 is a circuit diagram of a switching power supply module according to the third embodiment. FIG. 12 is an exploded perspective view of the switching power supply module according to the third embodiment. FIG. 13 is a top view and a side view of the switching power supply module according to the third embodiment.

A switching power supply module 10B according to the third embodiment differs from the switching power supply module 10A according to the second embodiment in that it has a structure corresponding to four-phase multiphase control. For the switching power supply module 10B, description of portions similar to those of the switching power supply module 10A will be omitted as appropriate.

### (Circuit Structure of Switching Power Supply Module 10B)

As illustrated in FIG. 11, the switching power supply module 10B includes a plurality of power semiconductor package elements (the power semiconductor package elements 21, 22, and 23 and a power semiconductor package element 24), a plurality of inductors (the inductors L31, L32, and L33 and an inductor L34), the input capacitor Ci, and the output capacitor Co.

The power semiconductor package element 24 includes a driving circuit 240, a power semiconductor element Q24H, and a power semiconductor element Q24L. The power semiconductor package element 24 has substantially the same structure as the power semiconductor package elements 21, 22, and 23.

The power semiconductor package element 24 is connected in parallel to the power semiconductor package elements 21, 22, and 23.

One terminal of the inductor L34 is connected to an output terminal of the power semiconductor package element 24. The other terminal of the inductor L34 is connected to the output-side wiring line LNo.

With such a structure, the switching power supply module 10B achieves four-phase multiphase control.

### (Structure of Switching Power Supply Module 10B)

As illustrated in FIGS. 12 and 13, the switching power supply module 10B differs from the switching power supply module 10A according to the second embodiment in that it includes four power semiconductor package elements and four inductor elements. For the switching power supply module 10B, description of portions similar to those of the switching power supply module 10A will be omitted as appropriate.

The switching power supply module 10B includes the multiple power semiconductor package elements 21, 22, 23, and 24, multiple inductor elements 31B, 32B, 33B, and 34B, the multiple capacitor elements 40, the multiple capacitor elements 50, the multiple connection conductors 60, multiple connection conductors 61B, a connection conductor 62B, the circuit boards 81, 82, and 83.

The power semiconductor package elements 21, 22, 23, and 24 are formed as surface-mounted analog ICs and correspond to the power semiconductor package elements 21, 22, 23, and 24, respectively, in the circuit diagram of FIG. 11.

The inductor elements 31B, 32B, 33B, and 34B are formed as surface-mounted elements. The inductor elements 31B, 32B, 33B, and 34B correspond to the inductors L31, L32, L33, and L34, respectively, in the circuit diagram of FIG. 11.

The inductor element 31B includes a metal conductor 311B and a magnetic core 312B. The inductor element 32B includes a metal conductor 321B and a magnetic core 322B. The inductor element 33B includes a metal conductor 331B and a magnetic core 332B. The inductor element 34B includes a metal conductor 341B and a magnetic core 342B. The schematic structures of the inductor elements 31B, 32B, 33B, and 34B are substantially the same as those of the inductor elements 31 and 32 according to the first embodiment.

The widths of the inductor elements 31B, 32B, 33B, and 34B are substantially one-fourth of the widths of the power semiconductor package elements 21, 22, 23, and 24.

The multiple connection conductors 61B have substantially the same structure as the multiple connection conductors 61A, and the connection conductor 62B has substantially the same structure as the connection conductor 62B.

Conductor patterns for implementing the switching power supply module 10B are formed on the multiple circuit boards 81, 82, and 83.

### (Mounting Structure of Circuit Board 81)

The multiple inductor elements 31B, 32B, 33B, and 34B, the multiple capacitor elements 50, and the multiple connection conductors 60 are mounted on the front surface 811 of the circuit board 81.

The inductor elements 31B, 32B, 33B, and 34B are mounted adjacent to each other in the second direction (the W direction in each drawing) on the circuit board 81.

The first terminal E3111 of the metal conductor 311B of the inductor element 31B, the first terminal E3211 of the metal conductor 321B of the inductor element 32B, the first terminal E3311 of the metal conductor 331B of the inductor element 33B, and a first terminal E3411 of the metal conductor 341B of the inductor element 34B are joined to land conductors on the front surface 811 of the circuit board 81 by a conductive joining material, such as solder.

The second terminal E3112 of the inductor element 31B, the second terminal E3212 of the inductor element 32B, the second terminal E3312 of the inductor element 33B, and a second terminal E3412 of the inductor element 34B are located near one end of the circuit board 81 in the first direction.

### (Mounting Structure of Circuit Board 82)

The power semiconductor package elements 23 and 24, the multiple capacitor elements 40, the multiple connection conductors 61B, and the connection conductor 62B are mounted on the circuit board 82.

The power semiconductor package element 23, the multiple connection conductors 61B, and the connection conductor 62B are mounted on the front surface 821 of the circuit board 82. The multiple connection conductors 61B are mounted at positions overlapping the multiple connection conductors 60 in plan view. In plan view, the connection conductor 62B is mounted at a position overlapping the second terminals of the multiple inductor elements 31B, 32B, 33B, and 34B.

The power semiconductor package element 24 and the multiple capacitor elements 40 are mounted on the rear surface 822 of the circuit board 82.

### (Mounting Structure of Circuit Board 83)

The power semiconductor package elements 21 and 22 and the multiple capacitor elements 40 are mounted on the circuit board 83.

The power semiconductor package element 21 and the multiple capacitor elements 40 are mounted on the front surface 831 of the circuit board 83. The power semiconductor package element 22 and the multiple capacitor elements 40 are mounted on the rear surface 832 of the circuit board 83.

### (Stacked Structure of Multiple Circuit Boards 81, 82, and 83)

The circuit board 82 is disposed on the front surface 811 side of the circuit board 81. The rear surface 822 of the circuit board 82 faces the front surface 811 of the circuit board 81. That is, the circuit boards 82 and 81 overlap each other as viewed in the height direction (the H direction in each drawing) (in plan view). The longitudinal direction of the circuit board 82 is parallel to the longitudinal direction of the circuit board 81. The circuit boards 82 and 81 are separated from each other in the height direction (the H direction in each drawing).

The circuit board 83 is disposed on the front surface 821 side of the circuit board 82. The rear surface 832 of the circuit board 83 faces the front surface 821 of the circuit board 82. That is, the circuit boards 83 and 82 overlap each other as viewed in the height direction (the H direction in each drawing) (in plan view). The longitudinal direction of the circuit board 83 is parallel to the longitudinal direction of the circuit board 82. The circuit boards 83 and 82 are separated from each other in the height direction (the H direction in each drawing).

The second terminal E3112 of the inductor element 31B, the second terminal E3212 of the inductor element 32B, the second terminal E3312 of the inductor element 33A, and the multiple connection conductors 60 are mounted on the rear surface 822 of the circuit board 82. As a result, the circuit boards 81 and 82 are electrically connected and physically connected.

The multiple connection conductors 61B and the connection conductor 62B are mounted on the rear surface 832 of the circuit board 83. As a result, the circuit boards 82 and 83 are electrically connected and physically connected.

In such a structure, in plan view of the switching power supply module 10B, the power semiconductor package elements 21, 22, 23, and 24 overlap one another. In plan view of the switching power supply module 10B, the inductor elements 31B, 32B, 33B, and 34B overlap the power semiconductor package elements 21, 22, 23, and 24.

With such a structure, the switching power supply module 10B can have substantially the same planar area as the switching power supply module 10 for performing two-phase multiphase control and the switching power supply module 10A for performing three-phase multiphase control, while achieving four-phase multiphase control. The switching power supply module 10B can achieve substantially the same advantageous effects as the switching power supply modules 10 and 10A.

In the switching power supply module 10B, the multiple connection conductors 61B overlap the multiple connection conductors 60 in plan view. As a result, in the switching power supply module 10B, connection distances between the input terminals PIH and PIL and the multiple power semiconductor package elements 21, 22, 23, and 24 can be shortened and a power loss can be suppressed.

In the switching power supply module 10B, the connection conductor 62B overlaps the second terminals of the multiple inductor elements 31B, 32n, 33n, and 34B. As a result, in the switching power supply module 10B, a connection distance between the power semiconductor package element 21 and the inductor element 31, a connection distance between the power semiconductor package element 22 and the inductor element 32n, a connection distance between the power semiconductor package element 23 and the inductor element 33n, and a connection distance between the power semiconductor package element 24 and the inductor element 34B can be shortened and a power loss can be suppressed.

Although the two-phase, three-phase, and four-phase multiphase controls have been described in the above first, second, and third embodiments, respectively, substantially the same advantageous effects can be achieved in a switching power supply module for performing five-phase or more multiphase control by appropriately applying the above-described structures of the switching power supply modules 10, 10A, and 10B to the switching power supply module and increasing the number of circuit boards to be stacked.

### Fourth Embodiment

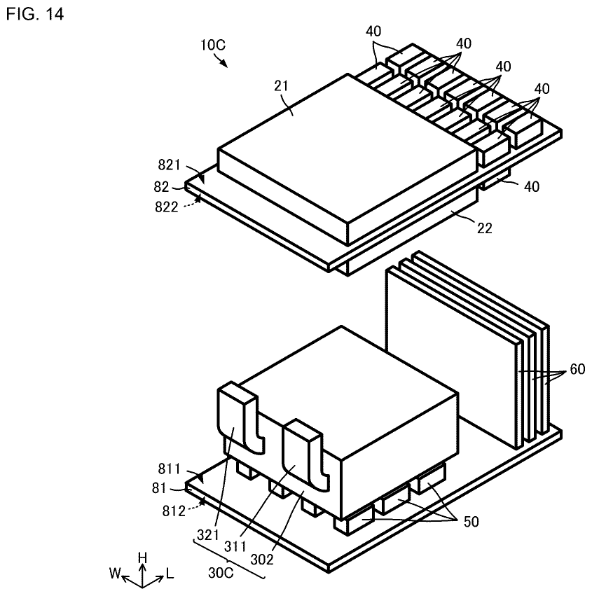

A switching power supply module according to a fourth embodiment of the present disclosure will be described with reference to drawings. FIG. 14 is an exploded perspective view of the switching power supply module according to the fourth embodiment.

A switching power supply module 10C according to the fourth embodiment differs from the switching power supply module 10 according to the first embodiment in that it includes a multi-inductor element 30C. For the switching power supply module 10C, description of portions similar to those of the switching power supply module 10 will be omitted as appropriate.

The switching power supply module 10C includes the multi-inductor element 30C. The multi-inductor element 30C includes the metal conductors 311 and 321 and a magnetic core 302.

The metal conductors 311 and 321 extend in parallel with a predetermined spacing therebetween. The metal conductors 311 and 321 have substantially the same structure as the metal conductors 311 and 321 in the inductor element 31 according to the first embodiment.

The magnetic core 302 accommodates respective main body portions of the metal conductors 311 and 321. Side surfaces of the main body portions of the metal conductors 311 and 321 are in close contact with the magnetic core 302.

With this structure, the multi-inductor element 30C has a structure in which the inductors L31 and L32 in the circuit illustrated in FIG. 1 are integrally formed.

The length of the multi-inductor element 30C is the same as the length of each of the inductor elements 31 and 32 according to the first embodiment. The width of the multi-inductor element 30C is substantially the same as, or smaller than, the widths of the power semiconductor package elements 21 and 22.

With such a structure, the switching power supply module 10C can achieve substantially the same advantageous effects as the switching power supply module 10.

### Fifth Embodiment

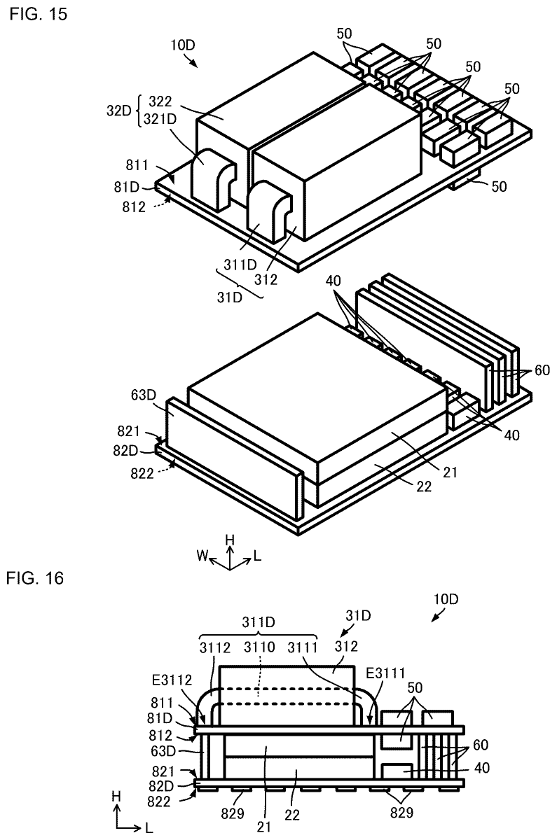

A switching power supply module according to a fifth embodiment of the present disclosure will be described with reference to drawings. FIG. 15 is an exploded perspective view of the switching power supply module according to the fifth embodiment. FIG. 16 is a side view of the switching power supply module according to the fifth embodiment.

A switching power supply module 10D according to the fifth embodiment differs from the switching power supply module 10 according to the first embodiment in that, in outline, positions of the circuit boards 81 and 82 in the height direction are interchanged. For the switching power supply module 10D, description of portions similar to those of the switching power supply module 10 will be omitted as appropriate.

The switching power supply module 10D includes the power semiconductor package elements 21 and 22, an inductor element 31D, an inductor element 32D, the multiple capacitor elements 40, the multiple capacitor elements 50, the multiple connection conductors 60, a connection conductor 63D, a circuit board 81D, and a circuit board 82D.

The inductor element 31D includes a metal conductor 311D and the magnetic core 312. The inductor element 31D differs from the inductor element 31 in the shape of the metal conductor 311D. The metal conductor 311D includes the main body portion 3110, the first end portion 3111, and the second end portion 3112. The first end portion 3111 and the second end portion 3112 both have shapes extending toward a bottom surface side of the magnetic core 312. The inductor element 32D includes a metal conductor 321D and the magnetic core 322, and has substantially the same structure as the inductor element 31D.

The circuit boards 81D and 82D are disposed apart from each other in the height direction such that the rear surface 812 of the circuit board 81D and the front surface 821 of the circuit board 82D face each other.

The inductor elements 31D and 32D and the multiple capacitor elements 50 are mounted on the front surface 811 of the circuit board 81D.

The first terminal E3111 and the second terminal E3112 of the inductor element 31D are both joined to the front surface 811 by a conductive joining material. The first terminal E3211 and the second terminal E3212 of the inductor element 32D are both joined to the front surface 811 by a conductive joining material.

The multiple capacitor elements 50 are mounted on the rear surface 812 of the circuit board 81D.

The power semiconductor package elements 21 and 22 and the multiple capacitor elements 40 are mounted on the front surface 821 of the circuit board 82D. The power semiconductor package elements 21 and 22 are mounted on the front surface 821 in a stacked state.

Multiple external connection conductors 829 are formed on the rear surface 822 of the circuit board 82D.

One end of each of the multiple connection conductors 60 in the height direction is mounted on the front surface 821 of the circuit board 82D. The other end of each of the multiple connection conductors 60 in the height direction is mounted on the rear surface 812 of the circuit board 81D. In plan view, the multiple connection conductors 60 overlap at least part of the multiple capacitor elements 50.

Similarly to the connection conductor 60, the connection conductor 63D is formed of metal or an insulating substrate having a conductor pattern formed thereon. One end of the connection conductor 63D in the height direction is mounted on the front surface 821 of the circuit board 82D. The other end of the connection conductor 63D in the height direction is mounted on the rear surface 812 of the circuit board 81D. In plan view, the connection conductor 63D overlaps the second terminal E3112 of the inductor element 31D and the second terminal E3212 of the inductor element 32D.

With such a structure, a power loss can be suppressed and heat dissipation efficiency per predetermined spatial volume can be increased in the switching power supply module 10D, similarly to the switching power supply module 10.

### Sixth Embodiment

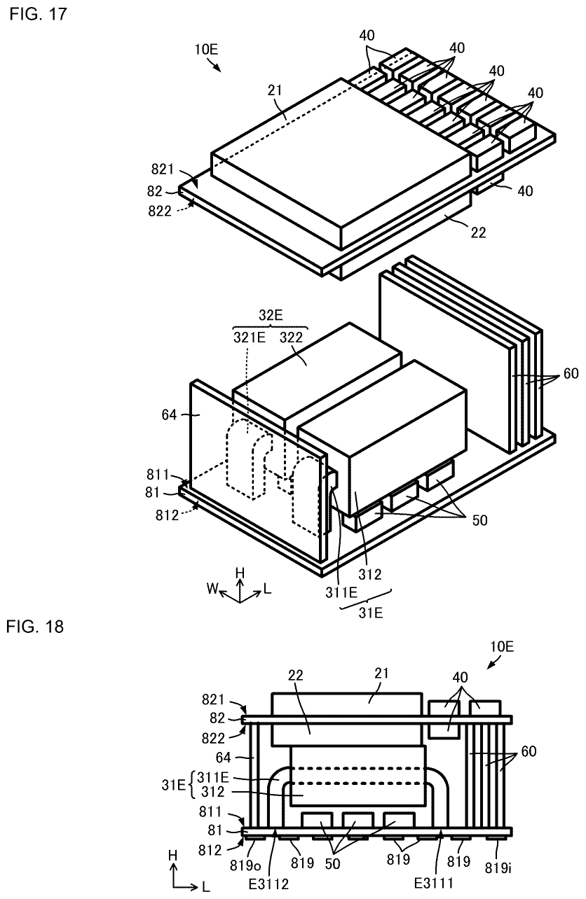

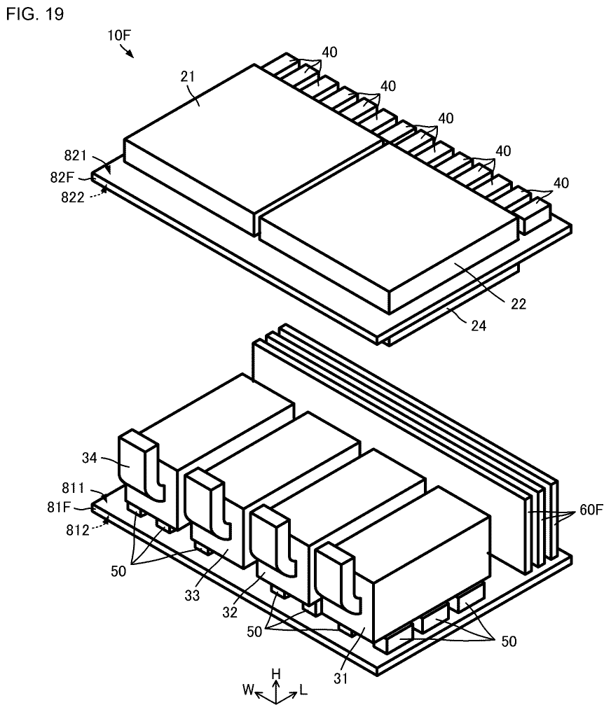

A switching power supply module according to a sixth embodiment of the present disclosure will be described with reference to drawings. FIG. 17 is an exploded perspective view of the switching power supply module according to the sixth embodiment. FIG. 18 is a side view of the switching power supply module according to the sixth embodiment.

A switching power supply module 10E according to the sixth embodiment differs from the switching power supply module 10 according to the first embodiment in that it includes an inductor element 31E, an inductor element 32E, and a connection conductor 64. For the switching power supply module 10E, description of portions similar to those of the switching power supply module 10 will be omitted as appropriate.

The switching power supply module 10E includes the inductor elements 31E and 32E and the connection conductor 64.

The inductor element 31E includes a metal conductor 311E and the magnetic core 312. The inductor element 31E differs from the inductor element 31 in the shape of the metal conductor 311E. The first end portion 3111 and the second end portion 3112 of the metal conductor 311E both have shapes extending toward a bottom surface side of the magnetic core 312. The inductor element 32E includes a metal conductor 321E and the magnetic core 322, and has substantially the same structure as the inductor element 31E.

The first terminal E3111 and the second terminal E3112 of the inductor element 31E are both joined to the front surface 811 by a conductive joining material. Similarly, the first terminal E3211 and the second terminal E3212 of the inductor element 32E are both joined to the front surface 811 by a conductive joining material.

Similarly to the connection conductor 60, a connection conductor 63E is formed of metal or an insulating substrate having a conductor pattern formed thereon. One end of the connection conductor 63E in the height direction is mounted on the front surface 811 of the circuit board 81. The other end of the connection conductor 63E in the height direction is mounted on the rear surface 822 of the circuit board 82. In plan view, the connection conductor 63E is disposed at end portions of the circuit boards 81 and 82 opposite to end portions at which the multiple connection conductors 60 are disposed. That is, the connection conductor 63E is disposed at a position close to the second terminal E3112 of the inductor element 31E and the second terminal E3212 of the inductor element 32E and is mounted on the front surface 811 of the circuit board 81.

With such a structure, a power loss can be suppressed and heat dissipation efficiency per predetermined spatial volume can be increased in the switching power supply module 10E, similarly to the switching power supply module 10.

### Seventh Embodiment

A switching power supply module according to a seventh embodiment of the present disclosure will be described with reference to drawings. FIG. 19 is an exploded perspective view of the switching power supply module according to the seventh embodiment.

A switching power supply module 10F according to the seventh embodiment differs from the switching power supply module 10 according to the first embodiment in that power semiconductor package elements are arranged also in the width direction of a circuit board. For the switching power supply module 10F, description of portions similar to those of the switching power supply module 10 will be omitted as appropriate.

The switching power supply module 10F includes the power semiconductor package elements 21, 22, 23, and 24, the inductor elements 31 and 32, an inductor element 33, an inductor element 34, the multiple capacitor elements 40, the multiple capacitor elements 50, multiple connection conductors 60F, a circuit board 81F, and a circuit board 82F.

The circuit of the switching power supply module 10F is a circuit capable of performing four-phase multiphase control, similarly to the switching power supply module 10B according to the third embodiment.

The circuit board 81F has a length in the second direction (the W direction) that is substantially twice that of the circuit board 81.

The inductor elements 31, 32, 33, and 34 are mounted on the front surface 811 of the circuit board 81F. The inductor elements 31, 32, 33, and 34 are mounted such that the extending directions of the main body portions thereof are parallel to the first direction (the L direction) of the circuit board 81F. The inductor elements 31, 32, 33, and 34 are mounted side by side in the second direction (the W direction) of the circuit board 81F.

The power semiconductor package elements 21 and 22 are mounted on the front surface 821 of the circuit board 82F. The power semiconductor package elements 21 and 22 are mounted side by side in the second direction (the W direction) of the circuit board 82F.

The power semiconductor package elements 23 and 24 are mounted on the rear surface 822 of the circuit board 82F. The power semiconductor package elements 23 and 24 are mounted side by side in the second direction (the W direction) of the circuit board 82F.

In plan view, a mounting region of the power semiconductor package elements 21 and 22, a mounting region of the power semiconductor package elements 23 and 24, and a mounting region of the inductor elements 31, 32, 33, and 34 overlap one another.

A length of the multiple connection conductors 60F in the second direction (the W direction) is substantially the same as the length of each of the circuit boards 81F and 82F in the second direction (the W direction). The multiple connection conductors 60F electrically and physically connect the circuit boards 81F and 82F.

With such a structure, a power loss can be suppressed and heat dissipation efficiency per predetermined spatial volume can be increased in the switching power supply module 10F, similarly to the switching power supply module 10.

<1> A switching power supply module comprising a circuit board and a plurality of power conversion circuits formed on the circuit board. Each of the plurality of power conversion circuits includes an inductor element, a power semiconductor package element, and a smoothing capacitor element. The inductor element includes a metal conductor mainly made of metal and a magnetic core, the metal conductor penetrates the magnetic core, and the metal conductor and the magnetic core are in close contact with each other at a portion where the metal conductor penetrates the magnetic core. The circuit board includes a first circuit board and a second circuit board. A plurality of the inductor elements constituting the plurality of power conversion circuits are mounted on the first circuit board. A plurality of the power semiconductor package elements constituting the plurality of power conversion circuits are mounted on the second circuit board. A width of the inductor element is smaller than a width of the power semiconductor package element. The plurality of inductor elements are arranged parallel to a mounting surface of the first circuit board on which the plurality of inductor elements are mounted, and are arranged along a width direction of the plurality of inductor elements. The first circuit board and the second circuit board are arranged such that the mounting surface of the first circuit board on which the plurality of inductor elements are mounted and mounting surfaces of the second circuit board on which the plurality of power semiconductor package elements are mounted are parallel to each other, the first circuit board and the second circuit board are separated from each other in a direction orthogonal to the mounting surfaces, and the first circuit board and the second circuit board overlap each other in plan view as viewed in the direction orthogonal to the mounting surfaces. The first circuit board and the second circuit board are electrically connected by a connection conductor that connects the first circuit board and the second circuit board in the direction orthogonal to the mounting surfaces.

<2> The switching power supply module according to <1>, wherein the number of the inductor elements and the number of the power semiconductor package elements are the same.

<3> The switching power supply module according to <1> or <2>, wherein the first circuit board has a first front surface on which the plurality of inductor elements are mounted, and a first rear surface on which an input/output terminal of the switching power supply module is formed. Also, the second circuit board is disposed on a side where the first front surface of the first circuit board is located.

<4> The switching power supply module according to <3>, wherein the second circuit board has a second front surface and a second rear surface facing the first front surface. A first power semiconductor package element of the plurality of power semiconductor package elements is mounted on the second front surface. A second power semiconductor package element of the plurality of power semiconductor package elements is mounted on the second rear surface. the first power semiconductor package element, the second power semiconductor package element, and the plurality of inductor elements overlap one another in the plan view.

<5> The switching power supply module according to <3> or <4>, wherein the metal conductor includes a main body portion penetrating the magnetic core, a first end portion that does not penetrate the magnetic core and forms a first terminal of the inductor element at one end of the main body portion, and a second end portion that does not penetrate the magnetic core and forms a second terminal of the inductor element at another end of the main body portion. The inductor element is disposed such that the main body portion is parallel to the mounting surfaces.

<6> The switching power supply module according to <5>, wherein each of the first end portion and the second end portion is formed to extend in a direction substantially orthogonal to a conduction direction of the main body portion. The first end portion and the second end portion extend from the main body portion in opposite directions. The first end portion is mounted on the first circuit board, and the second end portion is mounted on the second circuit board.

<7> The switching power supply module according to any one of <1> to <6>, wherein the connection conductor is formed of a columnar body or a plate mainly made of metal.

<8> The switching power supply module according to any one of <1> to <7>, wherein the connection conductor is formed of a conductor pattern formed on a glass epoxy substrate.

<9> The switching power supply module according to any one of <1> to <8>, wherein the power semiconductor package element is an element in which a power semiconductor element configured to perform a switching operation and a driving circuit configured to drive the power semiconductor element are integrally formed.

<10> The switching power supply module according to any one of <3> to <6>, wherein the smoothing capacitor element includes a plurality of input capacitor elements and a plurality of output capacitor elements. The plurality of output capacitor elements are mounted on the first circuit board, and the plurality of input capacitor elements are mounted on the second circuit board.

<11> The switching power supply module according to any one of <1> to <10>, wherein a planar area of the first circuit board and a planar area of the second circuit board are substantially the same.

<12> The switching power supply module according to any one of <1> to <11>, wherein each of the number of the plurality of power conversion circuits, the number of the plurality of inductor elements, and the number of the plurality of power semiconductor package elements is three or more. The circuit board further includes a third circuit board. The plurality of inductor elements are mounted on the first circuit board. The plurality of power semiconductor package elements are mounted on the second circuit board and the third circuit board. The third circuit board is disposed such that a mounting surface of the third circuit board on which the power semiconductor package element is mounted is parallel to a mounting surface of the second circuit board on which the power semiconductor package element is mounted, and the third circuit board and the second circuit board are separated from each other in a direction orthogonal to the mounting surfaces and overlap in the plan view. The second circuit board and the third circuit board are electrically connected by a connection conductor that connects the second circuit board and the third circuit board in the direction orthogonal to the mounting surfaces.

<13> The switching power supply module according to any one of <1> to <12>, further comprising a heat sink having an area that is substantially the same as an area of the power semiconductor package element, wherein the heat sink overlaps the power semiconductor package element in the plan view and is thermally connected to the power semiconductor package element.

What is claimed is:

1. A switching power supply module comprising:
a circuit board; and
a plurality of power conversion circuits on the circuit board,
wherein
each of the plurality of power conversion circuits includes an inductor element, a power semiconductor package element, and a smoothing capacitor element,
the inductor element includes a metal conductor including metal and a magnetic core, the metal conductor penetrates the magnetic core, and the metal conductor and the magnetic core are in contact with each other at a portion where the metal conductor penetrates the magnetic core,
the circuit board includes a first circuit board and a second circuit board,
a plurality of the inductor elements configuring the plurality of power conversion circuits are mounted on the first circuit board,
a plurality of the power semiconductor package elements configuring the plurality of power conversion circuits are mounted on the second circuit board,
a width of the inductor element is smaller than a width of the power semiconductor package element,
the plurality of inductor elements are parallel to a mounting surface of the first circuit board on which the plurality of inductor elements are mounted, and are arranged along a width direction of the plurality of inductor elements,
the first circuit board and the second circuit board are configured such that,
the mounting surface of the first circuit board on which the plurality of inductor elements are mounted and mounting surfaces of the second circuit board on which the plurality of power semiconductor package elements are mounted are parallel to each other,
the first circuit board and the second circuit board are separated from each other in a direction orthogonal to the mounting surfaces, and
the first circuit board and the second circuit board overlap each other in plan view as viewed in the direction orthogonal to the mounting surfaces, and
the first circuit board and the second circuit board are electrically connected by a connection conductor that connects the first circuit board and the second circuit board in the direction orthogonal to the mounting surfaces.

2. The switching power supply module according to claim 1, wherein
a number of the inductor elements and a number of the power semiconductor package elements are the same.

3. The switching power supply module according to claim 1, wherein
the first circuit board has,
a first front surface on which the plurality of inductor elements are mounted, and
a first rear surface on which an input/output terminal of the switching power supply module is configured, and
the second circuit board is on a side of the first front surface of the first circuit board is located.

4. The switching power supply module according to claim 3, wherein
the second circuit board has a second front surface and a second rear surface facing the first front surface,
a first power semiconductor package element of the plurality of power semiconductor package elements is mounted on the second front surface,
a second power semiconductor package element of the plurality of power semiconductor package elements is mounted on the second rear surface, and
the first power semiconductor package element, the second power semiconductor package element, and the plurality of inductor elements overlap one another in the plan view.

5. The switching power supply module according to claim 3, wherein
the metal conductor includes,
a main body portion penetrating the magnetic core,
a first end portion that does not penetrate the magnetic core and configures a first terminal of the inductor element at one end of the main body portion, and
a second end portion that does not penetrate the magnetic core and configures a second terminal of the inductor element at another end of the main body portion, and
the inductor element is disposed such that the main body portion is parallel to the mounting surfaces.

6. The switching power supply module according to claim 5, wherein
each of the first end portion and the second end portion extends in a direction substantially orthogonal to a conduction direction of the main body portion,
the first end portion and the second end portion extend from the main body portion in opposite directions,
the first end portion is mounted on the first circuit board, and
the second end portion is mounted on the second circuit board.

7. The switching power supply module according to claim 1, wherein
the connection conductor is configured of a columnar body or a plate including metal.

8. The switching power supply module according to claim 1, wherein
the connection conductor is a conductor pattern on a glass epoxy substrate.

9. The switching power supply module according to claim 1, wherein
the power semiconductor package element is an element in which a power semiconductor element configured to perform a switching operation and a driving circuit configured to drive the power semiconductor element are integral.

10. The switching power supply module according to claim 3, wherein
the smoothing capacitor element includes a plurality of input capacitor elements and a plurality of output capacitor elements,
the plurality of output capacitor elements are mounted on the first circuit board, and
the plurality of input capacitor elements are mounted on the second circuit board.

11. The switching power supply module according to claim 1, wherein
a planar area of the first circuit board and a planar area of the second circuit board are substantially the same.

12. The switching power supply module according to claim 1, wherein
each of a number of the plurality of power conversion circuits, a number of the plurality of inductor elements, and a number of the plurality of power semiconductor package elements is three or more,
the circuit board further includes a third circuit board,
the plurality of inductor elements are mounted on the first circuit board,
the plurality of power semiconductor package elements are mounted on the second circuit board and the third circuit board,
the third circuit board is disposed such that,
a mounting surface of the third circuit board on which the power semiconductor package element is mounted is parallel to a mounting surface of the second circuit board on which the power semiconductor package element is mounted, and
the third circuit board and the second circuit board are separated from each other in a direction orthogonal to the mounting surfaces and overlap in the plan view, and
the second circuit board and the third circuit board are electrically connected by a connection conductor that connects the second circuit board and the third circuit board in the direction orthogonal to the mounting surfaces.

13. The switching power supply module according to claim 1, further comprising:
a heat sink having an area that is substantially the same as an area of the power semiconductor package element,
wherein the heat sink overlaps the power semiconductor package element in the plan view and is thermally connected to the power semiconductor package element.

14. The switching power supply module according to claim 2, wherein
the first circuit board has,
a first front surface on which the plurality of inductor elements are mounted, and
a first rear surface on which an input/output terminal of the switching power supply module is configured, and
the second circuit board is on a side of the first front surface of the first circuit board is located.

15. The switching power supply module according to claim 4, wherein
the metal conductor includes,
a main body portion penetrating the magnetic core,
a first end portion that does not penetrate the magnetic core and configures a first terminal of the inductor element at one end of the main body portion, and
a second end portion that does not penetrate the magnetic core and configures a second terminal of the inductor element at another end of the main body portion, and
the inductor element is disposed such that the main body portion is parallel to the mounting surfaces.

16. The switching power supply module according to claim 2, wherein
the connection conductor is configured of a columnar body or a plate including metal.

17. The switching power supply module according to claim 2, wherein
the connection conductor is a conductor pattern on a glass epoxy substrate.

18. The switching power supply module according to claim 2, wherein
the power semiconductor package element is an element in which a power semiconductor element configured to perform a switching operation and a driving circuit configured to drive the power semiconductor element are integral.

19. The switching power supply module according to claim 4, wherein
the smoothing capacitor element includes a plurality of input capacitor elements and a plurality of output capacitor elements,
the plurality of output capacitor elements are mounted on the first circuit board, and
the plurality of input capacitor elements are mounted on the second circuit board.

20. The switching power supply module according to claim 2, wherein
a planar area of the first circuit board and a planar area of the second circuit board are substantially the same.
